(19) United States
(12) Patent Application Publication
(10) Pub. No.: US 2013/0042911 A1
(43) Pub. Date: Feb. 21, 2013

(54) SOLAR CELL AND METHOD OF FABRICATING THE SAME

(71) Applicants: Mi Hee JUNG, Daejeon (KR); Moo Jung Chu, Daejeon (KR); Yong Ju YUN, Daejeon (KR); Mangu KANG, Daejeon (KR)

(72) Inventors: Mi Hee JUNG, Daejeon (KR); Moo Jung Chu, Daejeon (KR); Yong Ju YUN, Daejeon (KR); Mangu KANG, Daejeon (KR)

(73) Assignee: ELECTRONICS AND TELECOMMUNICATIONS RESEARCH INSTITUTE, Daejeon (KR)

(21) Appl. No.: 13/549,851

(22) Filed: Jul. 16, 2012

(30) Foreign Application Priority Data
Aug. 19, 2011 (KR) 10-2011-0082645
Mar. 7, 2012 (KR) 10-2012-0023636

(51) Int. Cl. H01L 31/0224; H01L 31/18; C01G 1/02; B82Y 40/00; B82Y 99/00

(52) U.S. Cl. 136/256; 438/85; 264/104; 264/81; 977/948; 257/E31.126; 977/773

(57) ABSTRACT

Provided are a solar cell and a method of fabricating the same. The solar cell may include a first electrode including a first substrate attached with a first transparent conductive film and a metal oxide nanotube provided on the first substrate and adsorbed with a dye, a second electrode facing the first electrode, and an electrolyte filling between the first and second electrodes. In example embodiments, metal nanoparticles may be provided on an inner surface of the metal oxide nanotube.

### CROSS-REFERENCE TO RELATED APPLICATIONS

This U.S. non-provisional patent application claims priority under 35 U.S.C. §119 to Korean Patent Application Nos. 10-2011-0082645 and 10-2012-00023636, filed on Aug. 19, 2011 and Mar. 7, 2012, respectively, in the Korean Intellectual Property Office, the entire contents of which are hereby incorporated by reference.

### BACKGROUND OF THE INVENTION

Embodiments of the inventive concepts relate to a solar cell and a method of fabricating the same, and in particular, to a dye-sensitized solar cell and a method of fabricating the same.

A dye-sensitized solar cell is configured to include a light-sensitized dye generating electron-hole pairs from a visible light and an oxide semiconductor electrode formed of titanium oxide nano particles and used to deliver the generated electrons. In detail, if a visible light is incident to the dye, excited electrons are transported to titanium oxide particles serving as an n-type semiconductor and are used to form an electric current for reducing the dye. The dye-reduction process may be performed using an electrochemical oxidation-reduction reaction of I⁻/I₃⁻ included in a liquid electrolyte.

For the dye-sensitized solar cell with the titanium oxide nano particles, an electron delivering speed from the dye to TiO₂ is in a range of femto second 10⁻¹⁵ sec), while efficiency remains a low level of about 11%, by virtue of low electron mobility of TiO₂ and a recombination process occurring during electron transportation. Various TiO₂ structures have been discussed to overcome this difficulty. In addition, surface plasmon phenomena have been studied to improve photocurrent generation in various solar cells, such as schottky junction, dye-sensitized solar cell, and organic solar cell.

### SUMMARY

Embodiments of the inventive concepts provide a solar cell including a metal oxide structure with improved electron mobility.

Other embodiments of the inventive concepts provide a method of fabricating the solar cell.

Still other embodiments of the inventive concepts provide a method of forming a metal oxide nanotube, which may be used to improve efficiency of a solar cell.

Yet other embodiments of the inventive concepts provide a dye-sensitized solar cell with improved efficiency.

According to example embodiments of the inventive concepts, a solar cell may include a first electrode including a first substrate attached with a first transparent conductive film and a metal oxide nanotube provided on the first substrate and adsorbed with a dye, a second electrode facing the first electrode, and an electrolyte filling between the first and second electrodes.

In example embodiments, the metal oxide nanotube may have a hollow structure.

According to example embodiments of the inventive concepts, a method of fabricating a solar cell may include spinning a nano fiber including polymer compound onto a first substrate attached with a first transparent conductive film, forming a metal oxide layer on a surface of the nano fiber, selectively removing the nano fiber to form a nanotube of metal oxide, adsorbing a dye on the nanotube, disposing a second substrate attached with a second transparent conductive film to face the nanotube adsorbed with the dye, and filling an empty space between the first and second substrates with an electrolyte.

In example embodiments, the nano fiber including the polymer compound may be ejected onto the first substrate using an electrospinning method.

In example embodiments, the metal oxide layer may be formed on the surface of the nano fiber using an atomic layer deposition process.

In example embodiments, the nano fiber may be formed of a material including polyethylene oxide (PEO), the metal oxide layer may be formed of a material including TiO₂, and the selective removing of the nano fiber may be performed using deionized water.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a solar cell according to example embodiments of the inventive concept.

FIGS. 2A through 2C are diagrams exemplarily illustrating a method of fabricating a solar cell according to example embodiments of the inventive concept.

FIG. 3 is a schematic sectional view of an electrospinning apparatus.

FIGS. 4A through 4D are sectional views illustrating an ALD process according to example embodiments of the inventive concept.

FIG. 5A is an image showing a nano fiber of polymer compound according to example embodiments of the inventive concept.

FIG. 5B is an image showing a metal oxide nanotube according to example embodiments of the inventive concept.

FIG. 5C is a component analysis graph of the first electrode according to example embodiments of the inventive concept.

FIG. 6 is an experimental graph showing photocurrent densities with varying photo voltage.

FIG. 7 is a flow chart illustrating a method of forming metal oxide nanotubes according to other example embodiments of the inventive concept.

FIG. 8 is a sectional view illustrating a dye-sensitized solar cell according to other example embodiments of the inventive concept.

FIGS. 9A through 9E are schematic diagrams illustrating a method of forming TiO₂ nanotube with silver nanoparticles.

FIGS. 10A and 10B are SEM images of silver nanoparticles formed according to other example embodiments of the inventive concept.

FIG. 11A and FIG. 11B are SEM images of PEO polymer fibers formed according to other example embodiments of the inventive concept.

FIGS. 12A and 12B are SEM images of TiO₂ nanotubes with silver nanoparticles formed by other example embodiments of the inventive concept.

FIG. 13 is a graph showing photovoltage-photocurrent characteristics obtained from dye-sensitized solar cells.

FIGS. 14A and 14B are graphs showing interface resistance obtained from dye-sensitized solar cells.

FIG. 15 is a graph showing a result of intensity modulated photocurrent spectroscopy (IMPS) measured from the TiO₂ nanotube with silver nanoparticles.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element (s) or feature (s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

[Solar Cell]

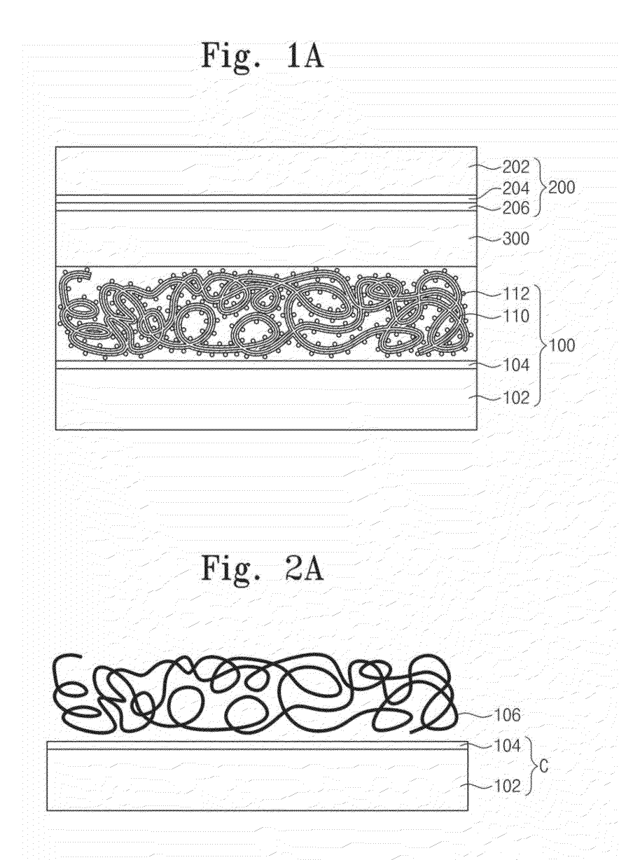

FIG. 1 is a sectional view illustrating a solar cell according to example embodiments of the inventive concept.

Referring to FIG. 1, a solar cell may include a first electrode 100, a second electrode 200 facing and spaced apart from the first electrode 100, and an electrolyte 300 (for example, provided in a liquefied form) filling between the first and second electrodes 100 and 200.

The first electrode 100 may serve as a cathode of the solar cell.

The first electrode 100 may include a first substrate 102, a first transparent conductive film 104, and a nanotube 110 formed of a metal oxide and adsorbed with a dye 112.

The first substrate 102 may be an optically transparent organic substrate or an optically transparent flexible polymer substrate. The first transparent conductive film 104 may be attached on a surface of the first substrate 102. The first transparent conductive film 104 may include at least one of an indium tin oxide (ITO) layer, an F-doped SnO₂ (FTO) layer, or a multi-layered structure including an antimony tin oxide (ATO) or FTO layer coated on an ITO layer.

The nanotube 110 may be provided on the surface of the first substrate 102, thereby intervening between, for example, the first substrate 102 and the second electrode 200. In example embodiments, the nanotube 110 may have a hollow structure and/or a smooth surface. The metal oxide for the nanotube 110 may be, for example, titanium oxide, tin oxide, and zinc oxide.

The dye 112 may be adsorbed onto the nanotube 110. The dye 112 may include a visible light absorbable ruthenium (Ru) complex having a ruthenium composite. In addition, the dye 112 may further include xanthine-based dyes (such as, rhodamine B, rose bengal, eosin, or erythrocin), cyanin-based dyes (such as, quinocyanin or cryptocyanin), basic dyes (such as, phenosafranine, capri-blue, tyrosine, or methylene blue), porphyrin-based compounds (such as, chlorophyll, zinc Zn porphyrin, or Mg porphyrin), azo-based dyes, phthalocyanine compounds, anthraquinone-based dyes, polycyclc quinone-based dyes, or any mixture thereof.

In other embodiments, the first electrode 100 may further include a blocking layer (not shown).

The blocking layer may be interposed between the first transparent conductive film 104 and the nanotube 110. In example embodiments, the blocking layer may improve a contact property between the first substrate 102 attached with the first transparent conductive film 104 and the nanotube 110 formed of the metal oxide and improve electron transportation from the nanotube 110 to the first substrate 102. In addition, the blocking layer may enable to control an electron outflow from the first substrate 102, thereby improving energy conversion efficiency.

The second electrode 200 may serve as an anode of the solar cell.

The second electrode 200 may include a second substrate 202, a second transparent conductive film 204, and a conduction layer 206.

The second substrate 202 may be an optically transparent organic substrate or an optically transparent flexible polymer substrate. The second transparent conductive film 204 may be provided on a surface of the second substrate 202. The second transparent conductive film 204 may include at least one of an ITO layer, a FTO layer, or a multi-layered structure including an ATO or FTO layer coated on an ITO layer. The conduction layer 206 may be provided on a surface of the second transparent conductive film 204 opposite to the second substrate 202. The conduction layer 206 may include platinum, carbon particles, conductive polymers, or any mixture thereof.

The electrolyte 300 may be provided to fill an empty space between the first and second electrodes 100 and 200 and/or an empty space in the nanotube 110 of the first electrode 100. The electrolyte 300 may include an oxidation-reduction derivative and an organic solvent. The oxidation-reduction derivative may be one selected the group consisting of lithium iodide (LiI), sodium iodide (NaI), potassium iodide (KI), lithium bromide (LiBr), sodium bromide (NaBr), potassium bromide (KBr), quarternary ammonium salt, imidazolium salt, and pyridinium salt. The organic solvent may be one selected the group consisting of ethylene carbonate, propylene carbonate, di-methyl carbonate, diethyl carbonate, ethyl methyl carbonate, tetra hydro furan, and gamma butyrolactone.

The solar cell described above may be a dye-sensitized solar cell. Hereinafter, a method of operating the dye-sensitized solar cell will be briefly described.

If a solar light is incident to the dye 112, electrons are excited and injected into a conduction band of the nanotube 110, which may be formed of a metal oxide. The injected electron is transported to an external circuit via a conductive element. The electron returns to the solar cell. The returned electron is delivered into to the dye 112 through the first electrode 100 and causes the reduction of the dye 112 which lacks electrons. As a result, the operation of the dye-sensitized solar cell can be completed.

Like this, the nanotube 110 of the solar cell may be used as a direct pathway for delivering the excited electrons to the external circuit, and this enables to increase efficiency of the solar cell. Furthermore, since the dye 112 may be adsorbed onto the nanotube 110, a contact area between the metal oxide and the dye 112 can be increased.

[Method of Fabricating a Solar Cell]

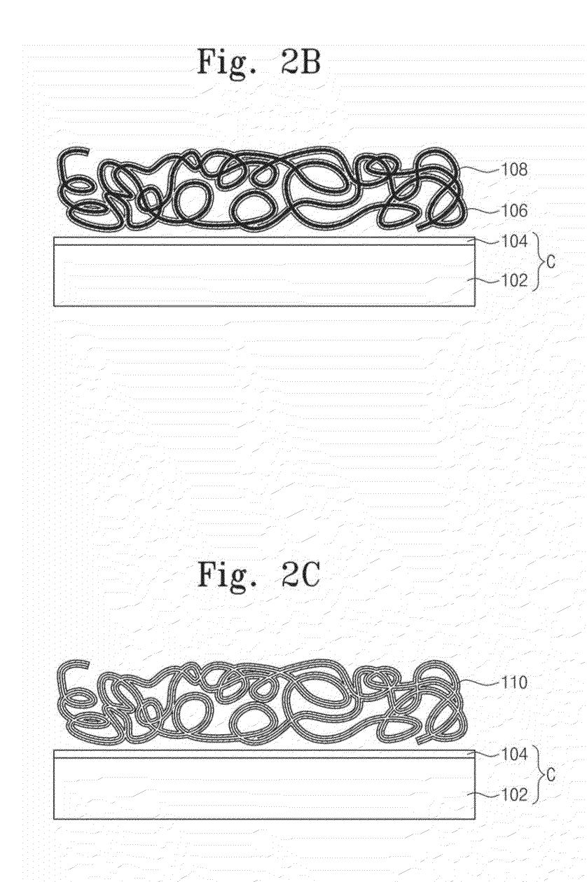

FIGS. 2A through 2C are diagrams exemplarily illustrating a method of fabricating a solar cell according to example embodiments of the inventive concept.

Referring to FIG. 2A, a nano fiber 106 may be formed on a first substrate 102 attached with a first transparent conductive film 104. The nano fiber 106 may be a polymer compound formed by an electrospinning method.

The electrospinning method is a technique using an electrical charge to draw fine fibers from a textile material solution. By using the electrospinning method, the fiber can have a very small thickness of, for example, nanometer to micrometer level. As the result of the thickness reduction of the fiber, the electrospun polymer compound may exhibit new properties, for example, an increase in a ratio of a surface area to a volume, an improvement in surface functional property, or an improvement in mechanical properties such as tension.

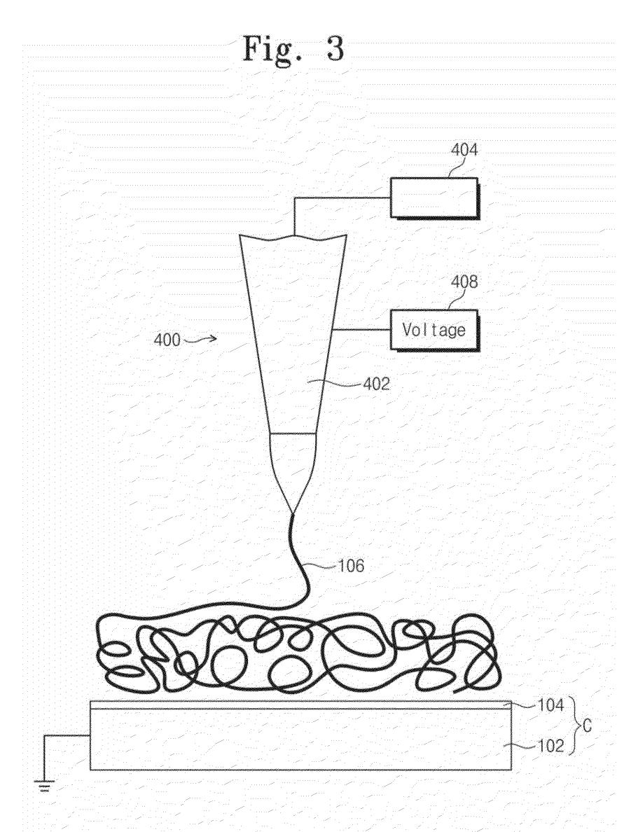

Hereinafter, an electrospinning apparatus will be briefly described. FIG. 3 is a schematic sectional view of an electrospinning apparatus.

Referring to FIG. 3, the electrospinning apparatus 400 may include a spinning solution supplying part 404, a spinning nozzle 402, a high voltage generating part 408, and a collector C.

The spinning solution supplying part 404 may be configured to store a source material (e.g., polymeric material) of the nano fiber 106, which may be dissolved in a solution or provided as a molten liquid.

The spinning nozzle 402 may be shaped like a cone or rod. A diameter of the fiber may be determined by a size of a hole provided at an end portion of the spinning nozzle 402. In example embodiments, the spinning nozzle 402 may be formed of a chemical-resistant, corrosion-resistant, and heat-resistant material.

The collector C may be disposed spaced apart from the end portion of the spinning nozzle 402. The collector C may be configured to gather a nano-sized fiber of polymer compound, which may be ejected from the spinning nozzle 402. In example embodiments, the collector C may be the first substrate 102 attached with the first transparent conductive film 104, and the polymer compound for the nano fiber 106 may be polyethylene oxide.

The spinning nozzle 402 may be connected to the high voltage generating part 408, while the collector C may be connected to a ground voltage.

Referring to FIG. 2B, a metal oxide layer 108 may be formed on a surface of the nano fiber 106 using an atomic layer deposition (ALD) process.

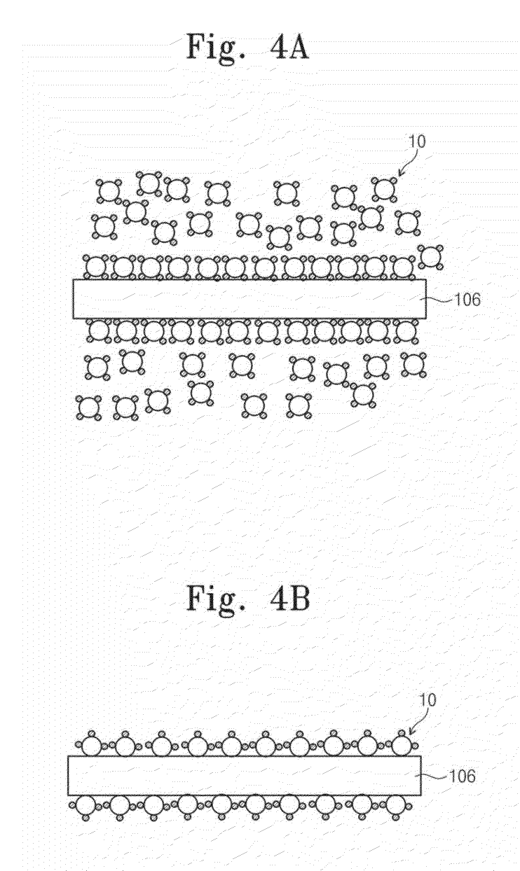

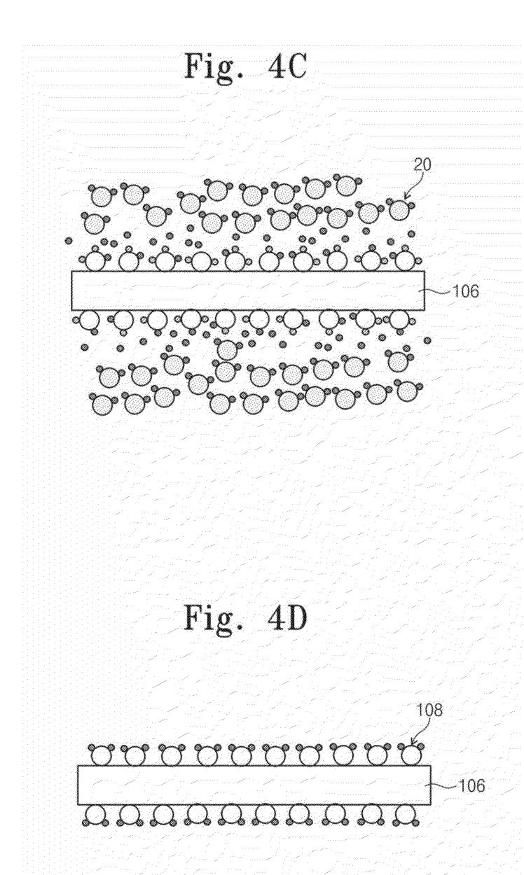

Hereinafter, the ALD process for forming the metal oxide layer 108 will be briefly described. FIGS. 4A through 4D are sectional views illustrating an ALD process according to example embodiments of the inventive concept.

Referring to FIG. 4A, a first precursor 10 may be supplied into a space for an ALD process. The first precursor 10 may be a material including a metallic element of the metal oxide layer 108. In example embodiments, the first precursor 10 may be a material including titanium, tin, or zinc. For example, in the case in which the metallic element is titanium, the first precursor 10 may be a titanium isopropoxide (TTIP) gas, which may be a chemical compound with the formula Ti(OCH(CH₃)₂)₄. Since the TTIP gas has a high vapor pressure at a room temperature, there is no necessity to supply an additional carrier gas into the space for the ALD process.

Referring to FIG. 4B, a purge gas may be supplied into the space for the ALD process. The purge gas may be one of inert gases (e.g., argon gas).

Referring to FIG. 4C, a second precursor 20 may be supplied into the space for the ALD process. In example embodiments, the second precursor 20 may be oxygen gas. After the supply of the oxygen gas, an operation of discharging plasma may be performed. Referring to FIG. 4D, a purge gas may be supplied into the space for the ALD process.

The formation of the metal oxide layer 108 may include performing at least one cycle including sequentially supplying the first precursor 10, the purge gas, the second precursor 20, and the purge gas into the space for the ALD process. By controlling the number of performing the cycle, the metal oxide layer 108 can be formed to have a desired thickness.

Referring to FIG. 2C, the nano fiber 106 may be removed from the metal oxide layer 108.

As the result of the removal of the nano fiber 106, the remaining metal oxide layer 108 may have a hollow structure and can serve as the nanotube 110. Since the nano fiber 106 has a nano-sized diameter, a hollow region delimited by the nanotube 110 can have a nano-sized diameter.

In example embodiments, in the case in which the polymer compound of the nano fiber 106 is formed of polyethylene oxide (PEO), the removal of the nano fiber 106 may include dissolving the polymeric fiber using deionized water of about 450° C. to 550° C.

Referring back to FIG. 1, the dye 112 may be adsorbed onto the nanotube 110 to form the first electrode 100. Thereafter, the second electrode 200 may be assembled to the first electrode 100, and the electrolyte 300 may be provided to fill an empty space between the first and second electrodes 100 and 200.

### EXPERIMENT

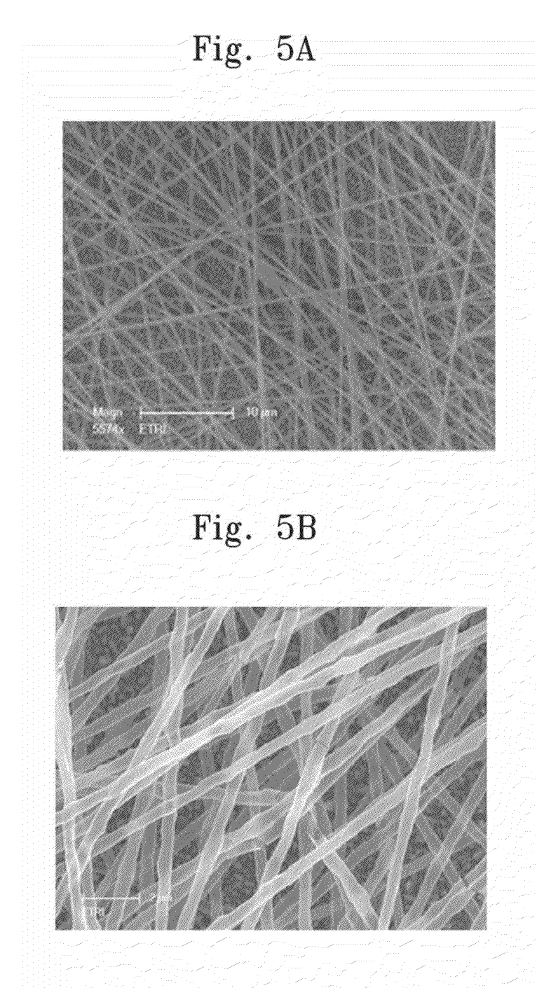

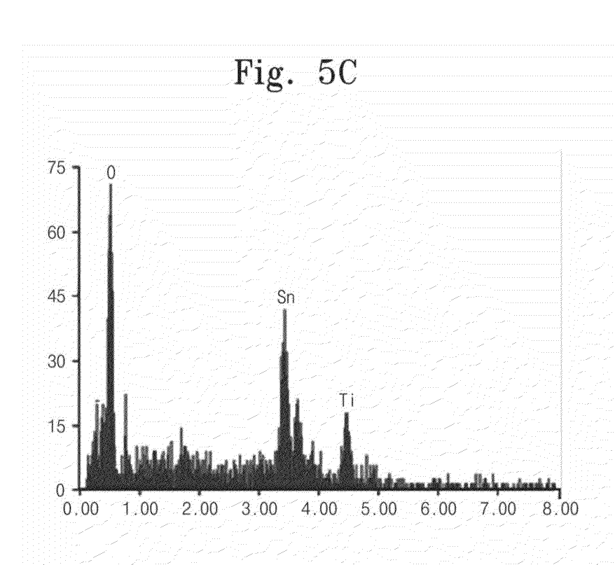

FIG. 5A is an image showing a nano fiber of polymer compound according to example embodiments of the inventive concept, and FIG. 5B is an image showing a metal oxide nanotube according to example embodiments of the inventive concept. FIG. 5C is a component analysis graph of the first electrode according to example embodiments of the inventive concept.

A spinning solution was prepared by dissolving PEO having a molecular mass of 400 k and a mass of 1 g in H₂O of 100 g and then stirring it at a temperature 60° C. for 4 hours. An electrospinning process was performed using electrospinning system (ESR100, NanoNC Co., Seoul, Korea). A spinning nozzle was applied with a voltage of 7 kV, and a first substrate serving as a collector was grounded. A distance between the collector and the spinning nozzle was 100 mm. The spinning solution was ejected with a rate of 0.1 mL/h from the spinning nozzle to form a PEO nano fiber on the collector. The PEO nano fiber is shown in FIG. 5A.

Thereafter, an ALD process was performed to deposit a layer of TiO₂ on a surface of the PEO nano fiber. The layer of TiO₂ was formed using titaniumisopropoxide [Ti(OCH(CH₃)₂)₄; TTIP] as a first precursor, without any carrier gas. O₂ plasma was used as a second precursor and argon gas with a purity of 99.999% was used as a purge gas. A TTIP precursor storing part was maintained at a temperature of 80° C., and a delivering conduit was maintained at a temperature of 60° C. A unit cycle of the ALD process for forming the layer of TiO₂ consisted of supplying the TTIP for 0.8 sec, performing a purge step with the argon gas of 600 sccm for 2 sec, supplying a reaction gas of O₂ for 0.5 sec, discharging O₂ plasma for 1.5 sec, and performing a purge step with the argon gas of 600 sccm for 2.5 sec. In other words, a total duration of the unit cycle was 7.3 sec, and the layer of TiO₂ was deposited to a thickness of 0.5 Å each cycle.

The table 1 below summarizes the unit cycle of the ALD process.

TABLE 1

| Step | 1 | 2 | 3 | 4 | 5 |
|---|---|---|---|---|---|
| TTIP | Supply | — | — | — | — |
| O₂ | — | — | Supply | Supply | — |
| Ar (purge gas) | — | Supply | — | — | Supply |
| plasma | off | off | off | on | off |
| Duration | 0.8 sec | 2.0 sec | 0.5 sec | 1.5 sec | 2.5 sec |

FIG. 5B shows a scanning electron microscope (SEM) image of PEO nano fibers deposited with the layer of TiO₂. As shown in FIG. 5B, the layer of TiO₂ deposited on the PEO nano fibers was smooth. This means that the PEO nano fiber did not chemically react with the first and second precursors.

Thereafter, the PEO nano fibers was selectively removed by dipping the PEO nano fibers deposited with the layer of TiO₂ in deionized water of 500° C. for 1 hour. As a result, hollow TiO₂ nanotubes were formed.

Referring to FIG. 5C, a component analysis was performed on the substrate provided with the TiO₂ nanotube and the ITO layer. As shown in FIG. 5C, tin (Sn), oxygen (O), and titanium (Ti), which are constituents of the substrate and the nanotube, were found.

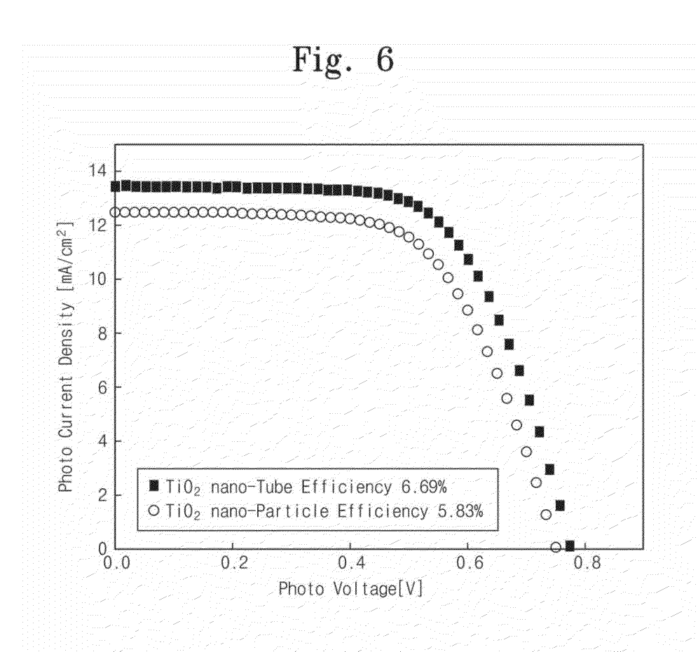

FIG. 6 is an experimental graph showing photocurrent densities with varying photo voltage. A curve indicated by solid squares depicts the result obtained from a solar cell including TiO₂ nanotubes according to example embodiments of the inventive concept, while other curve indicated by open circles depicts the result obtained from a solar cell including TiO₂ nano particles fabricated by a conventional process.

In FIG. 6, an x-axis represents a photo voltage [V] and a y-axis represents a photocurrent density [mA/cm²].

At the same photo voltage, the photocurrent density was greater in the solar cell including TiO₂ nanotubes according to example embodiments of the inventive concept than the solar cell including TiO₂ nano particles fabricated by a conventional process. From this result, it can be said that the solar cell including TiO₂ nanotubes according to example embodiments of the inventive concept showed superior charge collection efficiency, compared with the conventional solar cell.

A method of forming metal oxide nanotubes according to other example embodiments of the inventive concept and a dye-sensitized solar cell fabricated by the same will be described below.

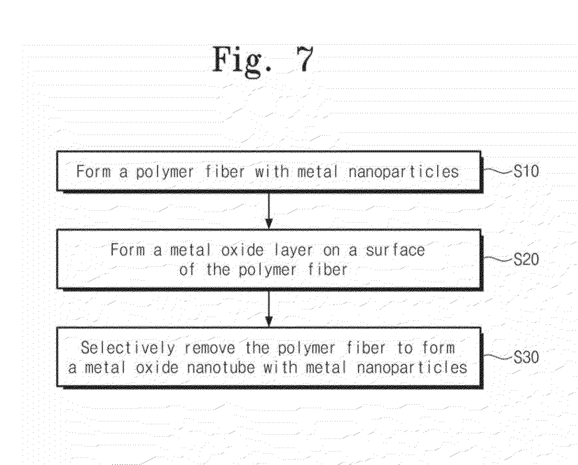

FIG. 7 is a flow chart illustrating a method of forming metal oxide nanotubes according to other example embodiments of the inventive concept.

Referring to FIG. 7, a polymer fiber provided with metal nanoparticles may be formed (in S10).

Metal nanoparticles may be distributed in water (H2O), and then, polymer may be mixed with the water. The solution, in which the metal nanoparticles and the polymer are mixed, may be spun to form the polymer fiber containing the metal nanoparticles. The polymer fiber containing the metal nanoparticles may be formed using one of electrospinning, melt-brown, electro-blown, flash spinning, and electrostatic melt-blown methods. The polymer fiber may serve as a template for forming a metal oxide nanotube.

Each of the metal nanoparticles may be covered with a layer of polyvinlpyrrolidone. Each of the metal nanoparticles may have a diameter ranging from about 15 nm to about 50 nm. The metal nanoparticles may include a material capable of exhibiting a plasmon effect. The plasmon effect may represent that when an external light is incident onto the metal nanoparticles, most of the light energy is delivered to free electrons in the metal nanoparticles, thereby resulting in movements of the free electrons along surfaces of the metal nanoparticles. The material capable of exhibiting the plasmon effect may be one of, for example, gold (Au), silver (Ag), copper (Cu), aluminum (Al), silicon (Si), and germanium (Ge).

The polymer may be one of polyurethane (PU), polyetherurethane, polyurethane copolymer, cellulose acetate, cellulose acetate butyrate, cellulose acetate propionate, polymethyl acrylate (PMA), polymethyl methacrylate (PMMA), polyacryl copolymer, polyvinylacetate (PVAc), polyvinylacetate copolymer, polyvinylalcohol (PVA), polyfurfurylalcohol (PPFA), polystyrene (PS), polystyrene copolymer, polyethylene oxide (PEO), polypropylene oxide (PPO), polyethyleneoxide copolymer, polypropylene oxide copolymer, polycarbonate (PC), polyvinylchloride (PVC), polycaprolactone (PCL), polyvinylpyrrolidone (PVP), polyvinyllidenefluoride (PVdF), polyvinyllidenefluoride copolymer, polyamide, and mixtures thereof.

A metal oxide layer may be deposited on a surface of the polymer fiber (in S20).

The metal oxide layer may be formed by an atomic layer deposition process. For example, the atomic layer deposition process may include supplying a metal oxide precursor in a process chamber and adsorbing the metal oxide precursor on the surface of the polymer fiber. In example embodiments, during the atomic layer deposition process, argon gas may be used as a purge gas, and an oxygen-containing gas may be used to generate oxygen plasma, which may be used for forming the metal oxide layer.

A portion of the metal oxide precursor may not participate in a reaction with the polymer fiber. The metal oxide layer may be formed on the surface of the polymer fiber to have a thickness ranging from about 50 Å to about 150 Å.

The metal oxide precursor may be provided in a solution containing at least one of titanium (Ti), zinc (Zn), tin (Sn), tungsten (W), strontium (Sr), or zirconium (Zr).

The metal oxide layer may be formed of titanium oxide (TiO₂), zinc oxide (ZnO), tin oxide (SnO2), tungsten oxide (WO3), strontium oxide (SrO), or zirconium oxide (ZrO2).

The polymer fiber may be selectively removed to form a metal oxide nanotube with metal nanoparticles (in S30).

For example, the removal of the polymer fiber may include dipping the polymer fiber provided with the metal oxide layer in deionized water and heating the resulting structure at temperature of about 400-600° C. for one hour. During this process, the polymer fiber may be selectively removed, but the metal nanoparticles may not be removed. Thus, the metal oxide nanotube with metal nanoparticles can be formed.

The metal nanoparticles may be adsorbed on an inner surface of the metal oxide nanotube. An outside diameter of the metal oxide nanotube may range from about 200 nm to about 300 nm. An inside diameter of the metal oxide nanotube may range from about 100 nm to about 200 nm.

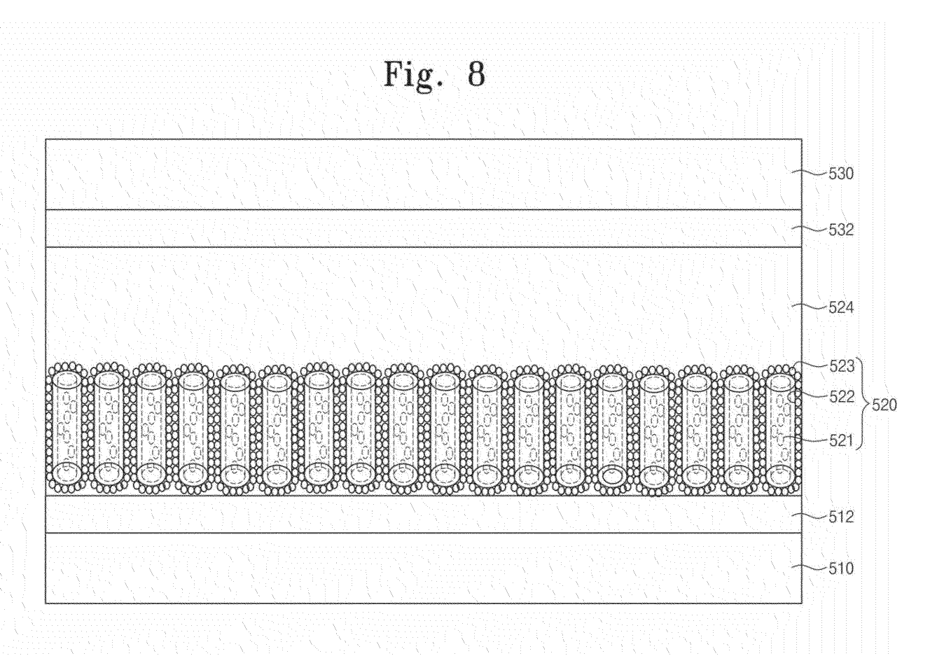

FIG. 8 is a sectional view illustrating a dye-sensitized solar cell according to other example embodiments of the inventive concept.

Referring to FIG. 8, the dye-sensitized solar cell may include a lower substrate 510 and an upper substrate 530. The lower substrate 510 may be spaced apart from the upper substrate 530. A transparent electrode 512 may be provided on a top surface of the lower substrate 510, and a counter electrode 532 may be provided on a bottom surface of the upper substrate 530. A semiconductor electrode layer 520 may be provided on a top surface of the transparent electrode 512, and an electrolyte solution layer 524 may be provided between the semiconductor electrode layer 520 and the counter electrode 532.

The lower substrate 510 may be a glass substrate or a transparent polymer substrate coated with a polymer layer. The transparent electrode 512 may include a conductive material. For example, the transparent electrode 512 may be formed of indium tin oxide (ITO), F-doped SnO2 (FTO), ZnO, antimony tin oxide (ATO), or carbon nanotube.

The semiconductor electrode layer 520 may include metal oxide nanotubes 522 containing metal nanoparticles 521. Dye molecules 523 may be adsorbed on surfaces of the metal oxide nanotubes 522. The metal oxide nanotubes 522 may be arranged in contact with a top surface of the transparent electrode 512. In example embodiments, each of the metal oxide nanotubes 522 may have a longitudinal axis perpendicular to the top surface of the transparent electrode 512. The metal nanoparticles 521 may be adsorbed on inner surfaces of the metal oxide nanotubes 522. A diameter of the metal oxide nanotube 522 may range from about 200 nm to about 300 nm. The metal nanoparticles 521 may include a material capable of exhibiting a plasmon effect (for example, gold (Au), silver (Ag), copper (Cu), aluminum (Al), silicon (Si), or germanium (Ge)). A thickness of the metal oxide layer of the metal oxide nanotubes 522 may influence the plasmon effect of the metal nanoparticles 521. For example, if the metal oxide layer is thick, an insufficient light may be incident to the metal nanoparticles 521 and thus, the plasmon effect may not occur. Considering this, the metal oxide layer may have a thickness ranging from about 50 Å to about 150 Å. The metal oxide nanotubes 522 may be formed of titanium oxide (TiO₂), zinc oxide (ZnO), tin oxide (SnO₂), tungsten oxide (WO₃), strontium oxide (SrO), or zirconium oxide (ZrO₂).

The dye molecules 523 may be ruthenium-based molecules or coumarin-based molecules. The dye molecules 523 may convert light energy into electric energy.

The upper substrate 530 may be a glass substrate or a transparent polymer substrate coated with a polymer layer. The counter electrode 532 may further include a catalyst layer. The catalyst layer may include platinum (Pt), gold (Au), ruthenium (Ru) or carbon nanotube.

The electrolyte solution layer 524 may include redox iodide electrolyte. For example, the electrolyte solution layer 524 may include an electrolyte of I³⁻/I⁻ obtained by dissolving 0.7 M 1-vinyl-3-methyloctyl-imidazolium iodide, 0.1 M LiI, and 40 mM I₂ (Iodine) in 3-methoxypropionitrile. Alternatively, the electrolyte solution layer 524 may include an acetonitrile electrolyte containing 0.6M butylmethylimidazolium, 0.02M I₂, 0.1M guanidinium thiocyanate, and 0.5M 4-tert-butylpyridine.

If a light is incident to the metal oxide nanotubes 522 of the semiconductor electrode layer 520, most of the light energy may be delivered to the metal nanoparticles 521, thereby resulting in movements of the free electrons along surfaces of the metal nanoparticles 521. The movements of the free electrons may lead to a change in polarizability of a neighboring material of the metal nanoparticles 521, thereby increasing absorbance of the neighboring material. Accordingly, light efficiency of the dye-sensitized solar cell can be improved.

In addition, since the metal nanoparticles 521 are adsorbed on the inner surfaces of the metal oxide nanotubes 522, it is possible to prevent the metal nanoparticles 521 from being reacted (e.g., corroded) with the electrolyte solution layer 524.

### Experimental Example

Referring to FIG. 3, a PEO polymer fiber 106 containing silver nanoparticles was formed using the electrospinning apparatus 400. To form the PEO polymer fiber 106, a paste containing silver nanoparticles and a polymer material mixed with each other was electrospun from the spinning nozzle 402.

In detail, silver nanoparticles covered with polyvinylpyrrolidone (PVP) were dissolved in 100 mL water. A concentration of the silver nanoparticle was 1×10⁻² to 1×10⁻⁶ mol/ml. The paste was formed by dissolving 1 g polyethylene oxide (PEO) with a molecular weight of 400 k in the water provided with the silver nanoparticles and agitating the resulting solution at a temperature of 60° C. for four hours.

A voltage generated by the high voltage generating part 408 was 7 kV, and a distance between the spinning nozzle 402 and the collector C was maintained to 100 mm.

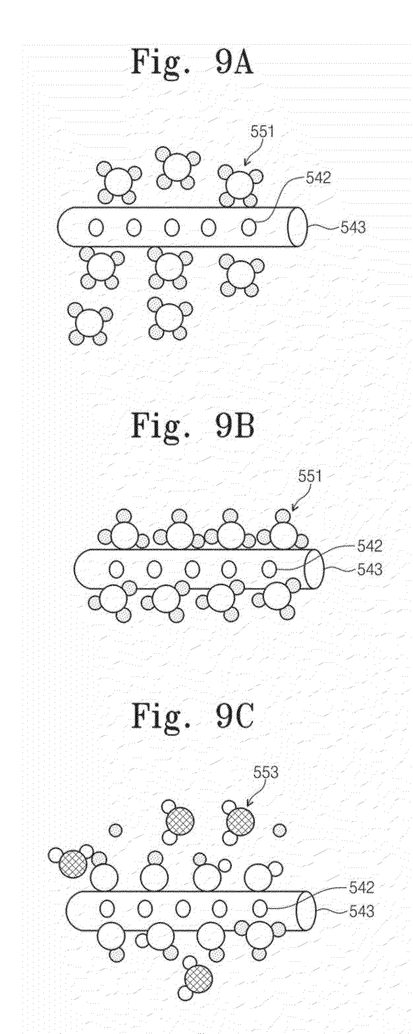

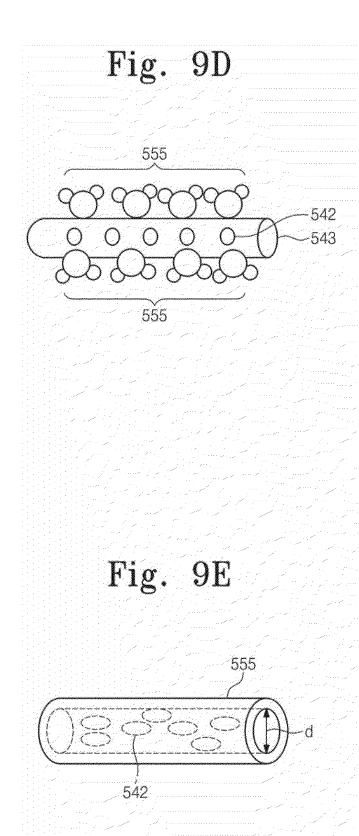

FIGS. 9A through 9E are schematic diagrams illustrating a method of forming TiO₂ nanotube with silver nanoparticles.

Referring to FIG. 9A, a PEO polymer fiber 543 with silver nanoparticles 542 was supplied into a chamber of an ALD apparatus, and then, titaniumisopropoxide [Ti (OCH (CH3)2)4; TTIP] precursor 551 was supplied into the chamber for 0.8 sec. A canister for storing the precursor 551 was maintained to a temperature of 80° C., and a delivery line was maintained to a temperature of 60° C.

Referring to FIG. 9B, argon gas with a purity of 99.999% (of 600 sccm) was supplied into the chamber for 2 sec to purge the chamber. The titaniumisopropoxide [Ti (OCH (CH3)2)4; TTIP] precursor 551 was adsorbed on a surface of the PEO polymer fiber 543.

Referring to FIG. 9C, a reaction gas 553 of oxygen (O2) was provided into the chamber for 0.5 sec, and then oxygen plasma was discharged for 1.5 sec. As a result, the oxygen reaction gas 553 did chemically react with the precursor 551.

Referring to FIG. 9D, argon gas (of 600 sccm) was supplied into the chamber for 2.5 sec to purge the chamber. As a result, a TiO₂ layer 555 was formed on a surface of the PEO polymer fiber 543. Thereafter, a cleaning process was performed to remove byproducts produced from the reaction between the oxygen reaction gas 553 and the precursor 551. The TiO₂ layer 555 was formed by repeating a unit cycle including steps depicted in FIGS. 9A through 9D. A total duration of the unit cycle was 7.3 sec, and the TiO₂ layer was deposited to a thickness of 0.5 Å each cycle. In the present example, the unit cycle was repeated 100 to 300 times, and as a result, the TiO₂ layer 555 was formed to have a thickness of about 50 Å to about 150 Å.

Referring to FIG. 9E, the PEO polymer fibers 543 were selectively removed by dipping the PEO polymer fibers 543 covered with the TiO₂ layer 555 in deionized water of 500° C. for 1 hour. As the result of the removal of the PEO polymer fiber 543, TiO₂ nanotubes with the silver nanoparticles 542 were formed. The TiO₂ nanotube had an inside diameter d ranging from about 100 nm to about 200 nm.

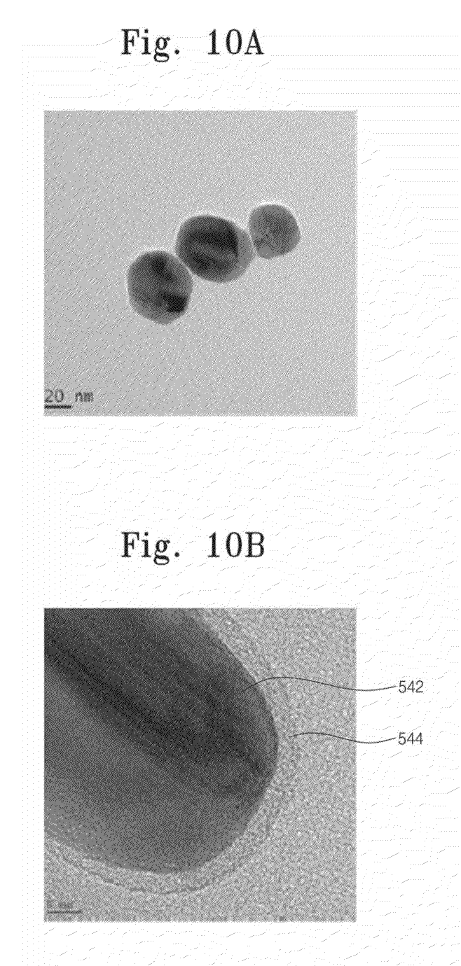

FIGS. 10A and 10B are SEM images of silver nanoparticles formed according to other example embodiments of the inventive concept.

Referring to FIGS. 10A and 10B, the silver nanoparticles 542 had a size of about 15-50 nm. From the magnified image of the silver nanoparticles 542, polyvinylpyrrolidone (PVP) 544 was found to cover surfaces of the silver nanoparticles 542.

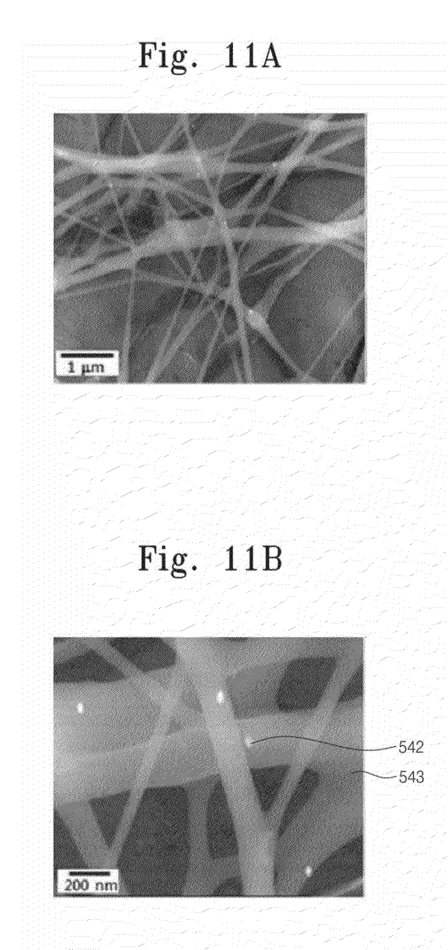

FIG. 11A and FIG. 11B are SEM images of PEO polymer fibers formed according to other example embodiments of the inventive concept.

Referring to FIGS. 11A and 11B, the PEO polymer fiber 543 had a diameter ranging from about 100 nm to about 200 nm, and as shown in FIG. 11B, the silver nanoparticles 542 were found to be provided in the PEO polymer fibers 543.

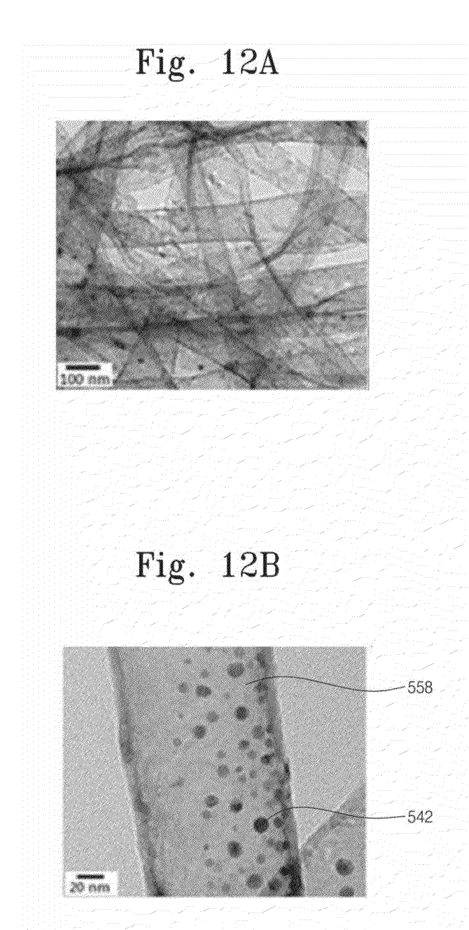

FIGS. 12A and 12B are SEM images of TiO₂ nanotubes with silver nanoparticles formed by other example embodiments of the inventive concept.

Referring to FIGS. 12A and 12B, the TiO₂ nanotube 558 had an inside diameter ranging from about 100 nm to about 200 nm, and as shown in FIG. 12B, the silver nanoparticles 542 were found to be adsorbed on an inner surface of the TiO₂ nanotube 558.

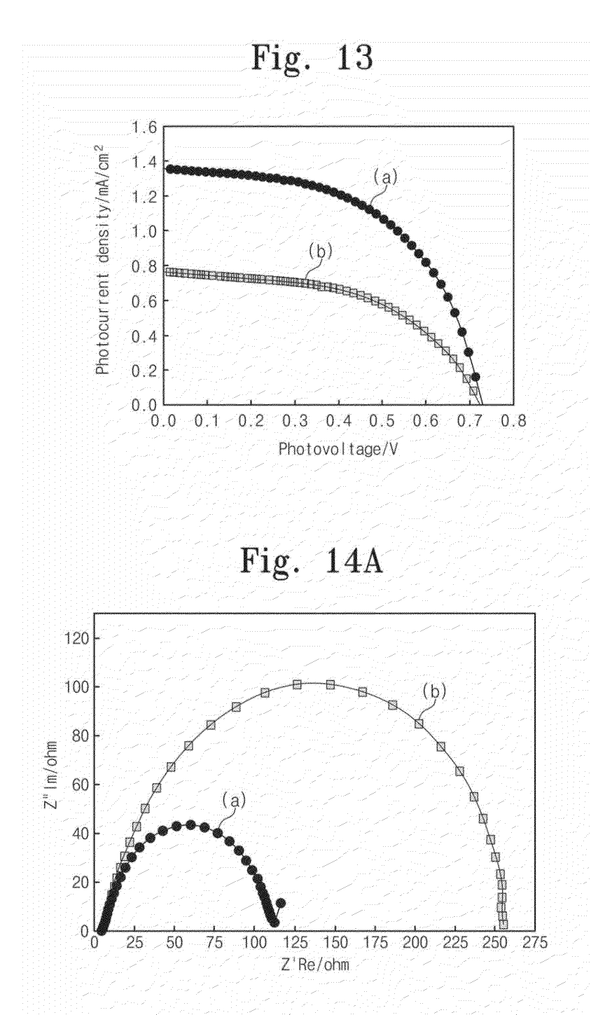

FIG. 13 is a graph showing photovoltage-photocurrent characteristics obtained from dye-sensitized solar cells.

In FIG. 13, a curve (a) was obtained from a dye-sensitized solar cell including TiO₂ nanotubes with silver nanoparticles (i.e., formed by according to other example embodiments of the inventive concept), and a curve (b) was obtained from a dye-sensitized solar cell including TiO₂ nanotubes without silver nanoparticles. In both solar cells, N719 dyes were adsorbed on surfaces of TiO₂ nanotubes, and the TiO₂ nanotubes were formed to have a thickness of 4 um and serve as a semiconductor electrode layer 520 of FIG. 8.

As shown in FIG. 13, at the same photovoltage, a photocurrent of the solar cell provided with silver nanoparticles (a) was higher than that of the solar cell without silver nanoparticles (b).

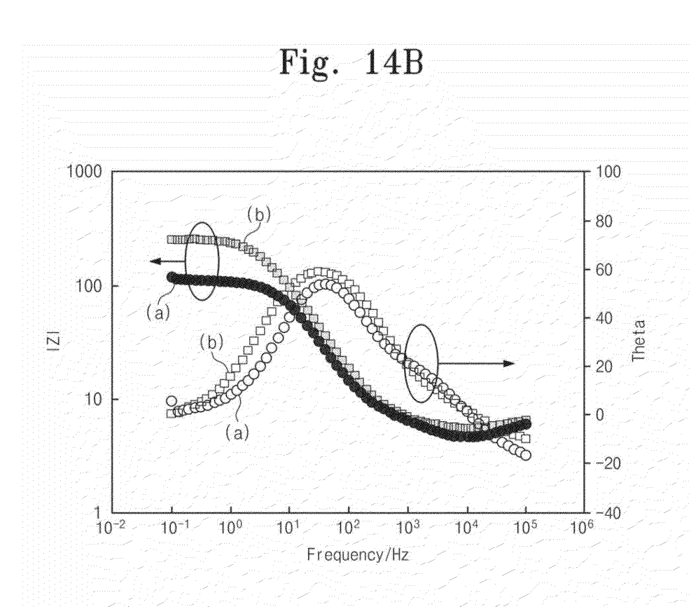

FIGS. 14A and 14B are graphs showing interface resistance obtained from dye-sensitized solar cells.

The curves (a) and (b) were obtained by measuring electrical resistance at interfaces of semiconductor electrodes of the dye-sensitized solar cells. The dye-sensitized solar cells were fabricated using the same process condition as those for FIG. 13. In other words, a curve (a) was obtained from a dye-sensitized solar cell including TiO₂ nanotubes with silver nanoparticles (i.e., formed by according to other example embodiments of the inventive concept), and a curve (b) was obtained from a dye-sensitized solar cell including TiO₂ nanotubes without silver nanoparticles.

In FIG. 14A, resistance at interface of the semiconductor electrode can be represented by sizes of semicircles given by the curves (a) and (b). From the graphs depicted in FIG. 14A, it can be found that TiO₂ nanotube with silver nanoparticles (a) has an interface resistance smaller than TiO₂ nanotube without silver nanoparticle (b). This means that TiO₂ nanotube with silver nanoparticles is effective in the transportation of electrons.

In FIG. 14B, ‘|Z|’ in the vertical axis represents the total resistance at semiconductor electrode interface, and ‘Theta’ in the vertical axis represents a slope of curves shown in FIG. 14A. It can be found that the total interface resistance of the TiO₂ nanotube with silver nanoparticles (a) is smaller than that of the TiO₂ nanotube without silver nanoparticles (b).

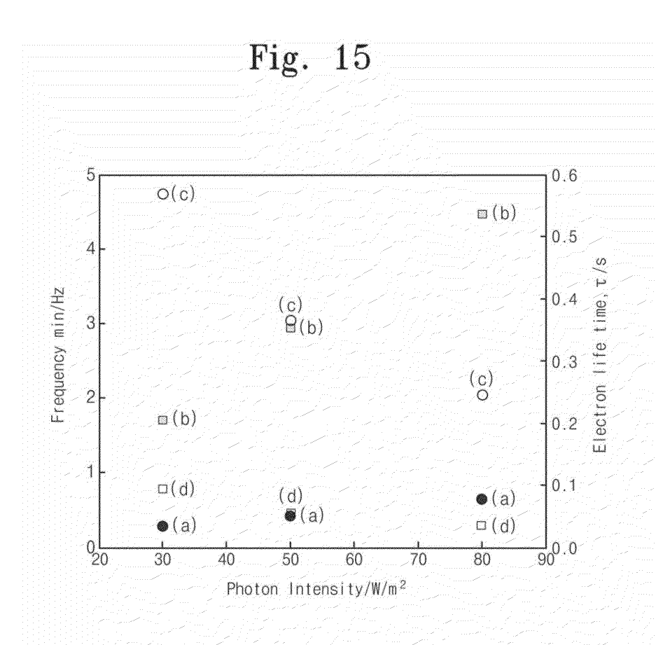

FIG. 15 is a graph showing a result of intensity modulated photocurrent spectroscopy (IMPS) measured from the TiO₂ nanotube with silver nanoparticles.

The dye-sensitized solar cells were fabricated using the same process condition as those for FIG. 13.

In the measurement, the dye-sensitized solar cell was operated with a LED light source (λ=525 nm).

Referring to FIG. 15, when the same energy is applied, an electron life time (c) at minimum frequency (a) of TiO₂ nanotube with silver nanoparticles is longer than an electron life time (d) at minimum frequency (b) of TiO₂ nanotube without silver nanoparticles. FIG. 15 shows that TiO₂ nanotube with silver nanoparticles is more effective in quenching electrons, compared with TiO₂ nanotube without silver nanoparticles.

According to example embodiments of the inventive concept, a solar cell is configured to have metal oxide nanotubes, which can be used as a pathway for directly delivering electrons. This enables to improve efficiency of the solar cell. In addition, a dye is adsorbed on the metal oxide nanotubes, thereby increasing a contact area between the metal oxide and the dye.

According to other example embodiments of the inventive concept, a method of forming a metal oxide nanotube may include forming nano fibers with metal nanoparticles, and then depositing a metal oxide layer on the nano fibers to form metal oxide nanotubes. The nano fibers (e.g., made of polymer) in the metal oxide nanotubes may be selectively removed. Accordingly, the metal nanoparticles may remain on inner surfaces of the metal oxide nanotubes. Thereafter, dye may be provided on the metal oxide nanotube to form a semiconductor electrode layer of a dye-sensitized solar cell. Since the metal nanoparticles exhibit a surface plasmon effect, the semiconductor electrode layer can have an improved absorbance property. This enables to increase optical efficiency of the dye-sensitized solar cell.

In addition, since the metal nanoparticles are adsorbed on the inner surface of the metal oxide nanotube, it is possible to prevent the metal nanoparticles from being corroded by the electrolyte solution layer.

While example embodiments of the inventive concepts have been particularly shown and described, it will be understood by one of ordinary skill in the art that variations in form and detail may be made therein without departing from the spirit and scope of the attached claims.

What is claimed is:

1. A method of fabricating a solar cell, comprising:
spinning a nano fiber including polymer compound onto a first substrate attached with a first transparent conductive film;
forming a metal oxide layer on a surface of the nano fiber;
selectively removing the nano fiber to form a nanotube of metal oxide;
adsorbing a dye on the nanotube;
disposing a second substrate attached with a second transparent conductive film to face the nanotube adsorbed with the dye; and
filling an empty space between the first and second substrates with an electrolyte.

2. The method of claim 1, wherein the nano fiber including the polymer compound is ejected onto the first substrate using an electrospinning method.

3. The method of claim 1, wherein the metal oxide layer is formed on the surface of the nano fiber using an atomic layer deposition process.

4. The method of claim 1, wherein the nano fiber is formed of a material including polyethylene oxide (PEO), and the metal oxide layer is formed of a material including TiO2, and the selective removing of the nano fiber is performed using deionized water.

5. A method of forming a metal oxide nanotube, comprising:
forming a polymer fiber provided with metal nanoparticles;
depositing a metal oxide layer on a surface of the polymer fiber; and
selectively removing the polymer fiber to form a metal oxide nanotube on inner surface of which the metal nanoparticles are provided.

6. The method of claim 5, wherein the polymer fiber is formed by spinning a solution containing the metal nanoparticles and the polymer mixed with each other.

7. The method of claim 5, wherein the metal nanoparticles are formed of a material exhibiting a plasmon effect.

8. The method of claim 7, wherein the metal nanoparticles include one of gold (Au), silver (Ag), copper (Cu), aluminum (Al), silicon (Si), and germanium (Ge).

9. The method of claim 5, wherein the forming of the metal oxide layer is performed by an atomic layer deposition process including:
supplying a metal oxide precursor to adsorb the metal oxide precursor on the surface of the polymer fiber;
performing a first purge step with argon gas to remove a non-adsorbed portion of the metal oxide precursor from the surface of the polymer fiber;
supplying oxygen gas to produce oxygen plasma and react the oxygen plasma with the metal oxide precursor adsorbed on the surface of the polymer fiber; and
performing a second purge step with argon gas to remove byproducts produced from the reaction and an non-reacted portion of the oxygen gas.

10. The method of claim 5, wherein the polymer fiber is formed of a material prevented from reacting with the metal oxide precursor, during the forming of the metal oxide nanotube.

11. The method of claim 5, wherein the metal nanoparticles are formed to have a diameter smaller than an inside diameter of the metal oxide nanotube.

12. The method of claim 11, wherein the metal oxide nanotube is formed to have the inside diameter of 100-200 nm.

13. The method of claim 5, wherein the metal oxide layer is formed to have a thickness of 50-150 Å.

14. A dye-sensitized solar cell, comprising:
an upper substrate and a lower substrate spaced apart from each other;
a transparent electrode provided on the lower substrate;
a semiconductor electrode layer provided on the transparent electrode; and
an electrolyte solution layer interposed between the semiconductor electrode layer and the upper substrate,
wherein the semiconductor electrode layer comprises metal oxide nanotubes and metal nanoparticles provided on inner surfaces of the metal oxide nanotubes.

15. The dye-sensitized solar cell of claim 14, wherein the metal nanoparticles are formed of a material exhibiting a plasmon effect.

16. The dye-sensitized solar cell of claim 15, wherein the metal nanoparticles include one of gold (Au), silver (Ag), copper (Cu), aluminum (Al), silicon (Si), and germanium (Ge).

17. The dye-sensitized solar cell of claim 14, wherein the metal oxide nanotubes are arranged in contact with a top surface of the transparent electrode, and each of the metal oxide nanotubes has a longitudinal axis perpendicular to the top surface of the transparent electrode.

18. The dye-sensitized solar cell of claim 15, further comprising a dye layer provided on an outer surface of the metal oxide nanotube.

19. A solar cell, comprising:
a first electrode including a first substrate attached with a first transparent conductive film and a metal oxide nanotube provided on the first substrate and adsorbed with a dye;
a second electrode facing the first electrode; and
an electrolyte filling between the first and second electrodes.

20. The solar cell of claim 19, wherein the metal oxide nanotube has a hollow structure.
